(19) United States
(12) Patent Application Publication
(10) Pub. No.: US 2025/0284073 A1
(43) Pub. Date: Sep. 11, 2025

(54) CHIP STRUCTURE AND SEMICONDUCTOR PACKAGE INCLUDING THE SAME

(71) Applicant: SAMSUNG ELECTRONICS CO., LTD., Suwon-si (KR)

(72) Inventor: Seokgeun AHN, Suwon-si (KR)

(73) Assignee: SAMSUNG ELECTRONICS CO., LTD., Suwon-si (KR)

(21) Appl. No.: 19/024,882

(22) Filed: Jan. 16, 2025

(30) Foreign Application Priority Data
Mar. 6, 2024 (KR) 10-2024-0032243

(51) Int. Cl. G02B 6/42; H01L 23/31; H01L 23/538; H01L 25/16

(52) U.S. Cl. CPC G02B 6/4248; G02B 6/4269; H01L 25/167; H01L 23/3135; H01L 23/5385; H01L 2225/06541; H01L 2225/06589

(57) ABSTRACT

Provided is a chip structure including a redistribution structure, an electronic integrated circuit (EIC) chip on the redistribution structure, a photonic integrated circuit (PIC) chip on the EIC chip, the PIC chip including a first groove recessed inwards from an upper surface of the PIC chip and a side surface of the PIC chip, and a waveguide having a first end exposed externally to the chip structure through the first groove, and a connector on the PIC chip, the connector including a connector waveguide passing through an inside of a body, a refractive index of the connector being greater than a refractive index of the body, and a condensing portion on a side surface of the body, wherein the condensing portion is configured to condense optical signals incident on the condensing portion from the connector waveguide to the waveguide of the PIC chip.

### CROSS-REFERENCE TO RELATED APPLICATION

This application claims priority to Korean Patent Application No. 10-2024-0032243, filed on Mar. 6, 2024, in the Korean Intellectual Property Office, the disclosure of which is incorporated by reference herein in its entirety.

### BACKGROUND

### 1. Field

Embodiments of the present disclosure relate to a semiconductor package and a method of manufacturing the same, and more particularly, to a chip structure including a photonic integrated circuit chip, and a semiconductor package including the chip structure.

### 2. Description of Related Art

In order to enhance the functionality of electronic devices and integration of components, the advantages of a semiconductor package are often taken into consideration. In the semiconductor package, various integrated circuits such as memory chips or logic chips can be mounted on a package substrate. In recent years, research on semiconductor packages, including photonic integrated circuits, has continued in an environment where data traffic in data centers and communication infrastructure has considerably increased.

### SUMMARY

One or more embodiments provide a chip structure in which optical fibers are separably bonded to each other and optical signals are condensed, and a semiconductor package including the chip structure.

One or more embodiments also provide a chip structure having a large tolerance when manufacturing thereof, and a semiconductor package including the chip structure.

Also, the objectives to be solved by the technical spirit are not limited to the objectives mentioned above, and other objectives can be understood by one of ordinary skill in the art from the following description.

According to an aspect of one or more embodiments, there is provided a chip structure including a redistribution structure, an electronic integrated circuit (EIC) chip on the redistribution structure, a photonic integrated circuit (PIC) chip on the EIC chip, the PIC chip including a first groove recessed inwards from an upper surface of the PIC chip and a side surface of the PIC chip, and a waveguide having a first end exposed externally to the chip structure through the first groove, and a connector on the PIC chip, the connector including a connector waveguide passing through an inside of a body, a refractive index of the connector being greater than a refractive index of the body, and a condensing portion on a side surface of the body, wherein the condensing portion is configured to condense optical signals incident on the condensing portion from the connector waveguide to the waveguide of the PIC chip.

According to another aspect of one or more embodiments, there is provided a semiconductor package including a package substrate, a semiconductor chip on the package substrate, a chip structure on the package substrate and spaced apart from the semiconductor chip, and a second molding layer on the package substrate and on the semiconductor chip and the chip structure, wherein the chip structure includes a redistribution structure on the package substrate, an electronic integrated circuit (EIC) chip on the redistribution structure, a photonic integrated circuit (PIC) chip on the EIC chip, the PIC chip including a first groove recessed inwards from an upper surface of the PIC chip and a side surface of the PIC chip, and a waveguide of which a first end is exposed externally to the semiconductor package through the first groove, and a connector on the PIC chip, the connector including a connector waveguide passing through an inside of a body, and a condensing portion contacting a first end of the connector waveguide, wherein the condensing portion is configured to condense optical signals incident on the condensing portion from the connector waveguide onto the waveguide of the PIC chip.

According to still another aspect of one or more embodiments, there is provided a semiconductor package including a package substrate, a semiconductor chip on the package substrate, a plurality of stack structures on the package substrate and spaced apart from the semiconductor chip, a chip structure on the package substrate and spaced apart from the semiconductor chip, a second molding layer on the package substrate, the semiconductor chip, and the chip structure, and a heat sink on the second molding layer, the semiconductor chip, and the plurality of stack structures, wherein the chip structure includes a redistribution structure on the package substrate, an electronic integrated circuit (EIC) chip on the redistribution structure, a first molding layer on the redistribution structure and the EIC chip, a photonic integrated circuit (PIC) chip on the EIC chip and the first molding layer, the PIC chip including a first groove recessed inwards from an upper surface of the PIC chip and a side surface of the PIC chip, and a waveguide having a first end is exposed externally to the semiconductor package through the first groove, a connector including a body on the PIC chip and configured to be separably bonded to an optical fiber module, a connector waveguide passing through the inside of the body, a refractive index of the connector waveguide being greater than a refractive index of the body, and a condensing portion at one side of the body and configured to condense optical signals emitted from the connector waveguide onto the waveguide of the PIC chip, and a dummy chip on the PIC chip, spaced apart from the connector, and below the heat sink in a vertical direction.

### BRIEF DESCRIPTION OF DRAWINGS

Embodiments will be more clearly understood from the following detailed description taken in conjunction with the accompanying drawings in which:

FIG. 1 is a plan view schematically illustrating a semiconductor package according to one or more embodiments;

FIG. 2 is a cross-sectional view taken along a line A-A′ of FIG. 1 and schematically illustrating the semiconductor package of FIG. 1;

FIG. 3 is an enlarged view schematically illustrating a portion EX1 of FIG. 2 of the semiconductor package of FIG. 2;

FIG. 4 is a view schematically illustrating the chip structure of FIG. 3 and an optical fiber module bonded to the chip structure;

FIG. 5 is an enlarged view schematically illustrating a portion EX2 of FIG. 3 of the chip structure of FIG. 3;

FIG. 6 is an enlarged view schematically illustrating a part of a chip structure according to one or more embodiments;

FIG. 7 is a cross-sectional view schematically illustrating a chip structure according to one or more embodiments;

FIG. 8 is a cross-sectional view schematically illustrating a chip structure according to one or more embodiments; and

FIG. 9 is a cross-sectional view schematically illustrating a semiconductor package according to one or more embodiments.

### DETAILED DESCRIPTION

Since various modifications and various embodiments are possible, example embodiments are illustrated in the drawings and described in detail in the detailed description. However, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

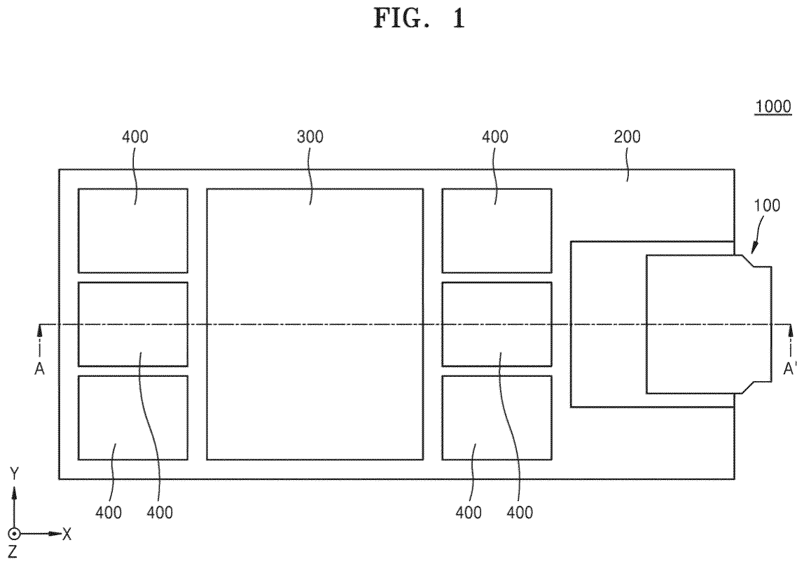

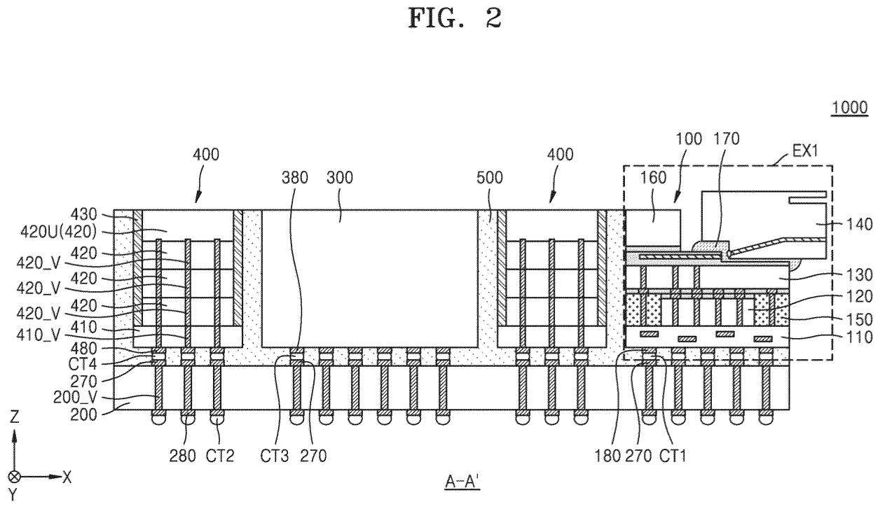

FIG. 1 is a plan view schematically illustrating a semiconductor package 1000 according to one or more embodiments. FIG. 2 is a cross-sectional view taken along a line A-A′ of FIG. 1 and schematically illustrating the semiconductor package 1000 of FIG. 1.

Referring to FIGS. 1 and 2, the semiconductor package 1000 may include a package substrate 200, a semiconductor chip 300, a plurality of stack structures 400, a second molding layer 500, and a chip structure 100.

Hereinafter, unless specifically defined, a direction that is in parallel to an upper surface of the package substrate 200 is defined as a first horizontal direction (X direction), and a direction that is perpendicular to the upper surface of the package substrate 200 is defined as a vertical direction (Z direction), and a direction that is perpendicular to the first horizontal direction (X direction) and the vertical direction (Z direction) is defined as a second horizontal direction (Y direction). A direction in which the first horizontal direction (X direction) and the second horizontal direction (Y direction) are synthesized with each other, is defined as a horizontal direction.

The package substrate 200 may be an interposer including a substrate and a through via 200_V that perforates the substrate. For example, the package substrate 200 may be a glass interposer including a substrate formed of glass and the through via 200_V that is a through glass via (TGV). However, embodiments are not limited thereto, and the package substrate 200 may be a silicon interposer including a substrate formed of silicon and the through via 200_V that is a through silicon via (TSV).

In one or more embodiments, the package substrate 200 may be a printed circuit board (PCB) including a core insulating layer including at least one material selected from the group consisting of phenol resin, epoxy resin, and polyimide.

In one or more embodiments, the package substrate 200 may further include an upper pad 270 disposed on the upper surface of the package substrate 200 and a lower pad 280 disposed on a lower surface of the package substrate 200. The upper pad 270 and the lower pad 280 may be electrically connected to each other by the through via 200_V or internal distribution. For example, each of the upper pad 270 and the lower pad 280 may include copper (Cu), nickel (Ni), stainless steel or beryllium copper.

In one or more embodiments, connection terminals CT2 may be attached to the lower pad 280 of the package substrate 200. The connection terminals CT2 may be configured to electrically and physically connect the package substrate 200 and an external device on which the package substrate 200 is mounted. The connection terminals CT2 may be formed from, for example, solder balls or solder bumps.

The semiconductor chip 300 may be mounted on the package substrate 200. The semiconductor chip 300 may include an active surface and an inactive surface facing the active surface. In one or more embodiments, the semiconductor chip 300 may include an application specific integrated circuit (ASIC).

In one or more embodiments, the semiconductor chip 300 may be mounted on the package substrate 200 so that the active surface of the semiconductor chip 300 may face the package substrate 200. For example, the semiconductor chip 300 may have a face down method and may be arranged on the package substrate 200.

In one or more embodiments, a variety of a plurality of individual devices may be disposed on the active surface of the semiconductor chip 300. For example, the plurality of individual devices may include various micro electronic devices, for example, complementary metal-oxide semiconductor (CMOS) transistors, metal-oxide-semiconductor filed effect transistors (MOSFETs), system large scale integration (LSI), image sensors such as CMOS imaging sensors (CISs) or the like, micro-electro-mechanical systems (MEMSs), active devices, passive devices, or the like.

In one or more embodiments, the semiconductor chip 300 may further include a lower pad 380 formed on a lower surface of the semiconductor chip 300. For example, the lower pad 380 of the semiconductor chip 300 may be electrically connected to a distribution structure formed on an active surface of the semiconductor chip 300.

The lower pad 380 of the semiconductor chip 300 and the package substrate 200 may be electrically connected to each other by a connection terminal CT3. However, embodiments are not limited thereto, and the lower pad 380 of the semiconductor chip 300 and the package substrate 200 may be electrically connected to each other by an anisotropic film (ACF), a nonconductive film (NCF), direct bonding or hybrid bonding.

The plurality of stack structures 400 may be disposed on the package substrate 200. For example, the plurality of stack structures 400 may be disposed adjacent to and to surround the semiconductor chip 300. For example, the plurality of stack structures 400 may be disposed at both sides of the semiconductor chip 300. The plurality of stack structures 400 may be electrically connected to the semiconductor chip 300 via the package substrate 200.

Each of the plurality of stack structures 400 may include a buffer chip 410, a plurality of core chips 420, and a core molding layer 430. The buffer chip 410 may be disposed at a bottom, and the plurality of core chips 420 may be stacked on the buffer chip 410 in a vertical direction (Z direction). The core molding layer 430 may be disposed on the buffer chip 410 and may surround the plurality of core chips 420. For example, an upper surface of the core molding layer 430 may be coplanar with the upper surface of a top core chip 420U. Thus, the upper surface of the top core chip 420U may be exposed externally to the semiconductor package 1000.

Each of the buffer chip 410 and the plurality of core chips 420 may include a semiconductor material, for example, silicon (Si) or germanium (Ge). However, embodiments are not limited thereto, and for example, each of the buffer chip 410 and the plurality of core chips 420 may include a compound semiconductor material such as silicon carbide (SiC), gallium arsenide (GaAs), indium arsenide (InAs), and indium phosphide (InP).

Each of the buffer chip 410 and the plurality of core chips 420 may include an active surface and an inactive surface facing the active surface. A semiconductor device including a plurality of various types of individual devices may be formed on the active surface of each of the buffer chip 410 and the plurality of core chips 420. Each of the buffer chip 410 and the plurality of core chips 420 may include a well doped with impurities that is a conductive region. Each of the buffer chip 410 and the plurality of core chips 420 may have various device isolation structures such as a shallow trench isolation (STI) structure.

The plurality of individual devices of the buffer chip 410 may include various micro electronic devices, for example, CMOS transistors, MOSFETs, system LSI, image sensors such as CISs) or the like, MEMSs, active devices, passive devices, or the like.

The plurality of individual devices of each of the plurality of core chips 420 may include a memory cell. For example, the memory cell may be a nonvolatile memory cell such as flash memory, phase-change random access memory (PRAM), magnetoresistive random access memory (MRAM), ferroelectric random access memory (FeRAM) or resistive random access memory (RRAM). In one or more embodiments, the memory cell may be a volatile memory cell such as dynamic random access memory (DRAM) or static random access memory (SRAM).

The plurality of individual devices of the buffer chip 410 may be electrically connected to a conductive region of the buffer chip 410, and the plurality of individual devices of each of the plurality of core chips 420 may be electrically connected to a conductive region of each of the plurality of core chips 420. For example, the conductive region of the buffer chip 410 may include a conductive pattern and an insulating layer surrounding the conductive pattern. For example, the conductive region of each of the plurality of core chips 420 may be substantially identical to the conductive region of the buffer chip 410.

In one or more embodiments, the buffer chip 410 may include a semiconductor chip that includes a serial-parallel conversion circuit and controls the plurality of core chips 420, and the plurality of core chips 420 may be a memory chip including memory cells. For example, a stack structure including the buffer chip 410 and the plurality of core chips 420 may be referred to as a high bandwidth memory (HBM), and the buffer chip 410 may be referred to as an HBM controller die, and each of the plurality of core chips 420 may be referred to as a DRAM die.

In one or more embodiments, a core chip disposed at a top of the plurality of core chips 420 may be referred to as a top core chip 420U. In FIG. 2, each of the plurality of stack structures 400 illustrates a stack of four core chips, but the number of core chips included in the plurality of stack structures 400 is not limited thereto.

In one or more embodiments, a core chip excluding the top core chip 420U of the plurality of core chips 420 may further include a through via 420_V that extends inwards from an upper surface of the core chip 420. The through via 420_V of each of the plurality of core chips 420 may be electrically connected to the conductive region of each core chip 420. However, embodiments are not limited thereto, and the top core chip 420U may include a through via 420_V.

Each of the plurality of core chips 420 may be electrically connected to an adjacent core chip or the buffer chip 410 through the through via 420_V. Thus, the plurality of core chips 420 may be electrically connected to the package substrate 200 through the through via 420_V. For example, the conductive region of the top core chip 420U may be electrically connected to the package substrate 200 through the through via 420_V of core chips stacked on lower parts of the stack structures in the vertical direction (Z direction).

In one or more embodiments, a thickness of each of the plurality of core chips 420, i.e., a length of each core chip 420 in the vertical direction (Z direction), may be about 20 μm to 80 μm. The thickness of each of the plurality of core chips 420 may have substantially the same value.

In one or more embodiments, a lower pad 480 may be disposed at a lower surface of the buffer chip 410. The lower pad 480 of the buffer chip 410 may be electrically connected to the through via 410_V of the buffer chip 410 or a distribution structure of the buffer chip 410.

The lower pad 480 of the buffer chip 410 and the upper pad 270 of the package substrate 200 may be electrically connected to each other by a connection terminal CT4. However, embodiments are not limited thereto, and the lower pad 480 of the buffer chip 410 and the package substrate 200 may be electrically connected to each other by an ACF, an NCF, direct bonding or hybrid bonding.

The chip structure 100 may be disposed on the package substrate 200. For example, the chip structure 100 may be disposed in an edge region of the package substrate 200. For example, one side surface of the redistribution structure 110 of the chip structure 100 may be on the same plane as a side surface of the package substrate 200. In a process of manufacturing the semiconductor package 1000, a dicing process of the semiconductor package 1000 may be performed based on a part of the chip structure 100, and the chip structure 100 may be disposed in the edge region of the package substrate 200.

In FIG. 1, the chip structure 100 is shown to be spaced apart from the semiconductor chip 300 with the plurality of stack structures 400 therebetween, but the arrangement of the chip structure 100 is not limited thereto.

The chip structure 100 may perform a procedure in which the semiconductor package 1000 communicates with an external source via optical signals. The chip structure 100 may receive the optical signals from the external source, convert the received optical signals into electrical signals, and may transmit the electrical signals to the semiconductor chip 300 and the plurality of stack structures 400 via the package substrate 200. In addition, the chip structure 100 may receive the electrical signals from the semiconductor chip 300 and the plurality of stack structures 400, may convert the received electrical signals into optical signals and may transmit the optical signals to the external source.

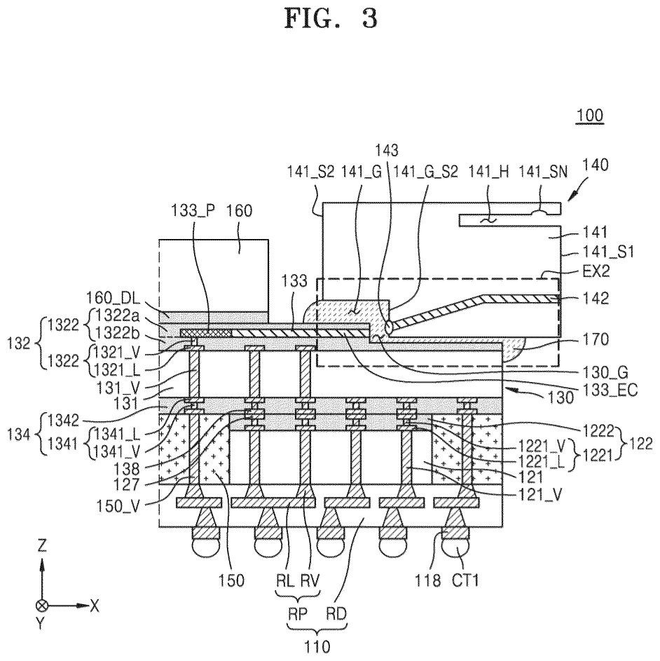

The chip structure 100 is described in detail with reference to FIGS. 3 through 5.

The second molding layer 500 may be disposed on the package substrate 200 and may surround the semiconductor chip 300, the plurality of stack structures 400, and the chip structure 100. For example, the second molding layer 500 may be in contact with a side surface of the semiconductor chip 300, side surfaces of the plurality of stack structures 400, and a side surface of the chip structure 100. The second molding layer 500 may protect the semiconductor chip 300, the plurality of stack structures 400, and the chip structure 100 from the outside of the semiconductor package 1000.

An upper surface of the second molding layer 500 may be coplanar with an upper surface of the semiconductor chip 300, upper surfaces of the plurality of stack structures 400, and an upper surface of the dummy chip 160 of the chip structure 100. The upper surface of the semiconductor chip 300, an upper surface of the top core chip 420U of the plurality of stack structures 400, and the upper surface of the dummy chip 160 of the chip structure 100 may be exposed externally to the semiconductor package 1000.

In one or more embodiments, a boundary surface between the second molding layer 500 and the core molding layer 430 of the plurality of stack structures 400 may be formed. In one or more embodiments, even when the configuration materials of the second molding layer 500 and the core molding layer 430 are the same, a boundary surface between the second molding layer 500 and the core molding layer 430 may be formed. For example, the second molding layer 500 and the core molding layer 430 may have different curing points of time so that a boundary surface between the second molding layer 500 and the core molding layer 430 may be formed.

In one or more embodiments, a boundary surface between the second molding layer 500 and the first molding layer 150 of the chip structure 100 may be formed. In one or more embodiments, even when the configuration materials of the second molding layer 500 and the first molding layer 150 are the same, a boundary surface between the second molding layer 500 and the first molding layer 150 may be formed. For example, the second molding layer 500 and the first molding layer 150 may have different curing points of time so that a boundary surface between the second molding layer 500 and the first molding layer 150 may be formed.

In one or more embodiments, the second molding layer 500 may include, for example, epoxy resin, polyimide resin, or the like. The second molding layer 500 may include, for example, an epoxy molding compound (EMC).

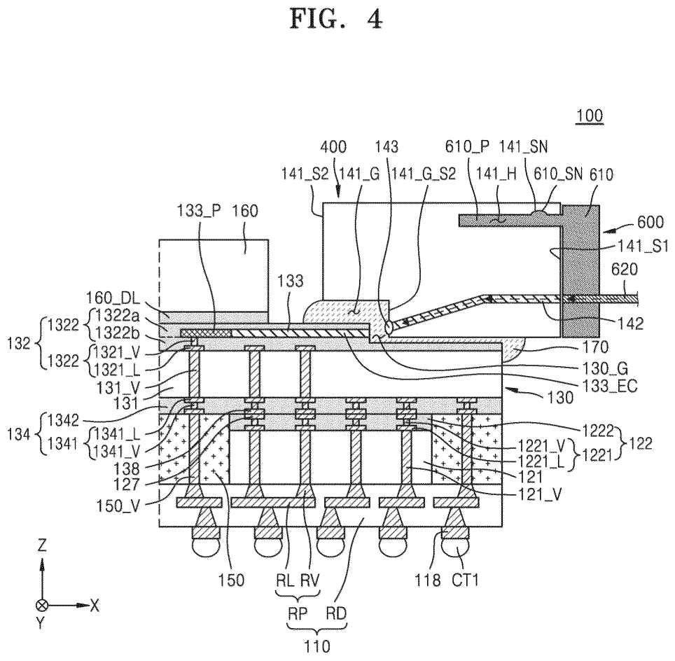

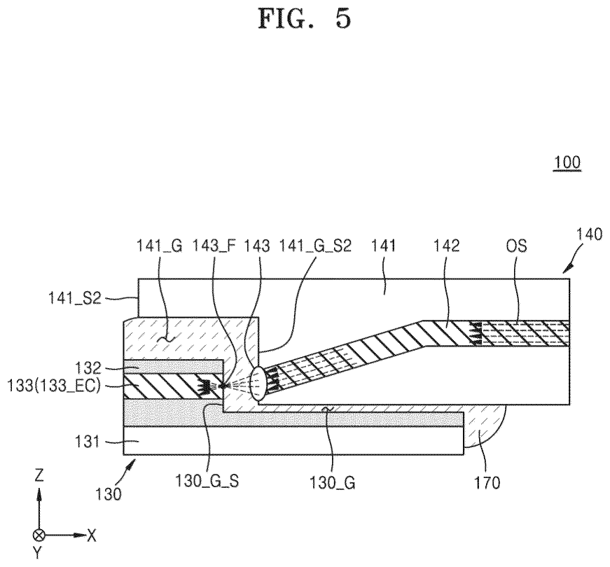

FIG. 3 is an enlarged view schematically illustrating a portion EX1 of FIG. 2 of the semiconductor package 1000 of FIG. 2. FIG. 4 is a view schematically illustrating the chip structure 100 of FIG. 3 and an optical fiber module 600 bonded to the chip structure 100. FIG. 5 is an enlarged view schematically illustrating a portion EX2 of FIG. 3 of the chip structure 100 of FIG. 3.

Referring to FIGS. 3 through 5, the chip structure 100 may include a redistribution structure 110, an electronic integrated circuit (EIC) chip 120, a first molding layer 150, a photonic integrated circuit (PIC) chip 130, a connector 140, and a dummy chip 160.

The redistribution structure 110 may be disposed on the package substrate 200. The redistribution structure 110 may include a redistribution pattern RP and a redistribution dielectric layer RD that surrounds the redistribution pattern RP. The redistribution dielectric layer RD may include an insulating material, for example, a photo imagable dielectric (PID) resin. In one or more embodiments, the redistribution dielectric layer RD may further include an inorganic filler. In one or more embodiments, the redistribution dielectric layer RD may have a multi-layered structure in which a redistribution pattern is arranged on each layer.

The redistribution pattern RP may include a redistribution line RL that extends in a horizontal direction, and a redistribution via RV that extends from the redistribution line RL in the vertical direction (Z direction). The redistribution line RL may be arranged on at least one surface of an upper surface and a lower surface of the redistribution dielectric layer RD or inside the redistribution dielectric layer RD. The redistribution via RV may pass through the redistribution dielectric layer RD to be connected to a part of the redistribution line RL.

The redistribution pattern RP may include a conductive material, for example, Cu, aluminum (Al), silver (Ag), tin (Sn), gold (Au), Ni, lead (Pb), titanium (Ti), or an alloy thereof.

In one or more embodiments, as the redistribution via RV approaches the EIC chip 120, a first horizontal direction (X direction) width and/or a second horizontal direction (Y direction) width of the redistribution via RV may be gradually decreased. For example, the horizontal area of the redistribution via RV may be decreased towards the EIC chip 120.

The EIC chip 120 may be disposed on the redistribution structure 110. The EIC chip 120 may be configured to interconnect the PIC chip 130 and the semiconductor chip (see 300 of FIG. 1) to each other. For example, the EIC chip 120 may convert electrical signals so that electrical signals converted by the PIC chip 130 may match with the semiconductor chip (see 300 of FIG. 1).

In one or more embodiments, an area of the EIC chip 120 may be less than an area of the redistribution structure 110 in the horizontal directions (X and Y directions). For example, the side surface of the EIC chip 120 may be disposed on the upper surface of the redistribution structure 110. A part of the redistribution structure 110 may not be covered by the EIC chip 120.

The EIC chip 120 may include a first substrate 121, a first through via 121_V, and a first distribution structure 122. The first substrate 121 of the EIC chip 120 may include an active surface and an inactive surface facing the active surface. The first distribution structure 122 may be formed on the active surface of the first substrate 121. The first through via 121_V may extend from the upper surface of the first substrate 121 to the lower surface of the first substrate 121. The first through via 121_V may be electrically connected to the plurality of individual devices on the first distribution structure 122 and/or the active surface of the first substrate 121.

In one or more embodiments, the first substrate 121 may include a semiconductor material such as silicon (Si). However, embodiments are not limited thereto, and for example, the first substrate 121 may include a semiconductor material such as germanium (Ge).

In one or more embodiments, the EIC chip 120 may include a plurality of individual devices used to interconnect the PIC chip 130 and the semiconductor chip (see 300 of FIG. 1). The plurality of individual devices of the EIC chip 120 may be disposed on the active surface of the first substrate 121. For example, the EIC chip 120 may include CMOS drivers, transimpedance amplifiers, or the like so as to perform functions such as controlling high frequency signaling of the PIC chip 130.

The first distribution structure 122 may include a first distribution pattern 1221 and a first distribution dielectric layer 1222 that surrounds the first distribution pattern 1221. The first distribution pattern 1221 may include a first distribution line 1221_L that extends in the horizontal direction, and a first distribution via 1221_V that extends from the first distribution line 1221_L in the vertical direction (Z direction). The first distribution pattern 1221 may be electrically connected to the plurality of individual devices and the lower pad 128.

In one or more embodiments, the EIC chip 120 may be arranged on the redistribution structure 110 so that the active surface of the first substrate 121 may be directed toward the PIC chip 130. For example, the EIC chip 120 may have a face up method and may be arranged on the redistribution structure 110.

The first through via 121_V may be electrically connected to the redistribution pattern RP of the redistribution structure 110. For example, the first through via 121_V may be configured to electrically connect the redistribution pattern RP of the redistribution structure 110 and the first distribution structure 122 to each other.

The EIC chip 120 may further include an upper pad 127. For example, the upper pad 127 may be a region that is not covered by the first distribution dielectric layer 1222 of the first distribution pattern 1221 disposed on a top but is exposed externally to the semiconductor package 1000.

The first molding layer 150 may be disposed on the redistribution structure 110 and may surround the EIC chip 120. The first molding layer 150 may be configured to cover a side surface of the EIC chip 120. For example, the sum of the area of the lower surface of the EIC chip 120 and the area of the lower surface of the first molding layer 150 may be the same as the area of the upper surface of the redistribution structure 110.

In one or more embodiments, the side surface of the first molding layer 150, the side surface of the redistribution structure 110, and the side surface of the PIC chip 130 may be coplanar with each other.

In one or more embodiments, the chip structure 100 may further include a mold through via 150_V that passes through the first molding layer 150. The mold through via 150_V may extend from the upper surface of the first molding layer 150 to the lower surface of the first molding layer 150. The mold through via 150_V may be configured to electrically connect the redistribution structure 110 and the PIC chip 130 to each other. In one or more embodiments, the mold through via 150_V may be spaced apart from the EIC chip 120 in the horizontal direction.

In one or more embodiments, the redistribution structure 110 may further include a lower pad 118 disposed at the lower surface of the redistribution structure 110. The lower pad 118 may be electrically connected to the redistribution pattern RP of the redistribution structure 110.

In one or more embodiments, connection terminals CT1 may be attached to the lower pad 118 of the redistribution structure 110. The connection terminals CT1 may be configured to electrically and physically connect the chip structure 100 and the package substrate (see 200 of FIG. 2) on which the chip structure 100 is mounted, to each other. The connection terminals CT1 may be formed from solder balls or solder bumps, for example. However, a method of mounting the chip structure 100 on the package substrate (see 200 of FIG. 2) is not limited thereto.

The PIC chip 130 may be disposed on the EIC chip 120. For example, the PIC chip 130 may be disposed on the EIC chip 120 and the first molding layer 150.

The PIC chip 130 may include a second substrate 131, an upper distribution structure 132, a lower distribution structure 134, a waveguide 133, and a photonic component 133_P. For example, the upper distribution structure 132 and the waveguide 133 may be disposed on the upper surface of the second substrate 131. The lower distribution structure 134 may be disposed on the lower surface of the second substrate 131.

For example, the PIC chip 130 may include a second through via 131_V that extends from the upper surface to the lower surface of the second substrate 131. The second through via 131_V may be configured to electrically connect the upper distribution structure 132 and the lower distribution structure 134 to each other.

In one or more embodiments, the second substrate 131 may include a semiconductor material such as Si. However, embodiments are not limited thereto, and for example, the second substrate 131 may include a semiconductor material such as Ge.

The lower distribution structure 134 may include a lower distribution pattern 1341, and a lower distribution dielectric layer 1342 that surrounds the lower distribution pattern 1341. The lower distribution pattern 1341 may include a lower distribution line 1341_L that extends in the horizontal direction, and a lower distribution via 1341_V that extends from the lower distribution line 1341_L in the vertical direction (Z direction). The lower distribution pattern 1341 may be electrically connected to a second through via 134_V and the mold through via 150_V.

The PIC chip 130 may further include a lower pad 138. For example, the lower pad 138 may be a region that is not covered by the lower distribution dielectric layer 1342 of the lower distribution pattern 1341_L disposed on a bottom but is exposed externally to the semiconductor package 1000.

The lower distribution structure 134 of the PIC chip 130 and the first distribution structure 122 of the PIC chip 120 may be electrically connected to each other. In one or more embodiments, the lower pad 138 of the PIC chip 130 and the upper pad 127 of the EIC chip 120 may be diffused and bonded to each other by heat and thus may be formed as one body. While the lower pad 138 and the upper pad 127 are diffused and bonded to each other, the lower distribution dielectric layer 1342 of the lower distribution structure 134 and the first distribution dielectric layer 1222 of the first distribution structure 122 may be diffused and bonded to each other by heat and may be formed as one body. The PIC chip 130 and the EIC chip 120 may be bonded to each other by using a hybrid bonding method.

However, a method of bonding the PIC chip 130 and the EIC chip 120 is not limited thereto, and the PIC chip 130 and the EIC chip 120 may be electrically connected to each other by using an ACF, an NCF, or a connection terminal.

The upper distribution structure 132 may include an upper distribution pattern 1321, and an upper distribution dielectric layer 1322 that surrounds the upper distribution pattern 1321. The upper distribution pattern 1321 may include an upper distribution line 1321_L that extends in the horizontal direction, and an upper distribution via 1321_V that extends from the upper distribution line 1321_L in the vertical direction (Z direction). The upper distribution pattern 1321 may be electrically connected to the second through via 131_V and the photonic component 133_P.

The upper distribution dielectric layer 1322 may include a first upper distribution dielectric layer 1322b and a second upper distribution dielectric layer 1322a. In one or more embodiments, the first upper distribution dielectric layer 1322b may be an oxide layer such as silicon oxide or the like. The second upper distribution dielectric layer 1322a may be a dielectric layer including one or more layers such as silicon oxide, silicon nitride, or a combination thereof. In one or more embodiments, the configuration material of the first upper distribution dielectric layer 1322b and the second upper distribution dielectric layer 1322a may be the same.

The waveguide 133 may be a patterned silicon layer and may extend from the first upper distribution dielectric layer 1322b in the horizontal direction. For example, the waveguide 133 may be buried in the upper distribution dielectric layer 1322. For example, the waveguide 133 may be disposed on the first upper distribution dielectric layer 1322b and may be covered by the second upper distribution dielectric layer 1322a.

In one or more embodiments, the waveguide 133 may be a silicon waveguide including Si, and the upper distribution dielectric layer 1322 may be a buried oxide (BOX) layer. However, embodiments are not limited thereto, and the waveguide 133 may be covered by an oxide layer isolated from the upper distribution dielectric layer 1322.

The waveguide 133 may be connected to the photonic component 133_P. The photonic component 133_P may convert optical signals OS into electrical signals and electrical signals into optical signals OS. In one or more embodiments, the photonic component 133_P may include a photodetector, a laser diode, and a modulator.

While the optical signals OS are input to the chip structure 100, the photodetector may detect the optical signals OS input to the PIC chip 130. The PIC chip 130 may detect the optical signals OS input through the photodetector to convert the optical signals OS into electrical signals.

While the chip structure 100 outputs the optical signals OS, the EIC chip 120 may transmit the electrical signals to the modulator. The modulator may input signals corresponding to the received electrical signals to a laser emitted by a laser diode and convert the laser emitted by the laser diode into the optical signals OS.

The PIC chip 130 may include a first groove 130_G. The first groove 130_G may be recessed to the inside of the PIC chip 130 from the upper surface and the side surface of the PIC chip 130. For example, the inside of the first groove 130_G may be open to the side surface of the PIC chip 130. In one or more embodiments, the first groove 130_G may be referred to as a V-groove.

The first groove 130_G may be adjacent to the waveguide 133. For example, one end of the waveguide 133 may be exposed externally to the semiconductor package 1000 by the first groove 130_G. The waveguide 133 may include an edge coupler 133_EC. The edge coupler 133_EC may be disposed on one end of the waveguide 133 exposed to the first groove 130_G. The PIC chip 130 may input/output the optical signals OS to/from the outside through the edge coupler 133_EC of the waveguide 133.

In one or more embodiments, the vertical level of the bottom surface of the first groove 130_G may be lower than the vertical level of the waveguide 133 in the vertical direction (Z direction). In FIG. 3, the first groove 130_G is formed in the upper redistribution structure 110 but may be formed in the upper redistribution structure 110 and the second substrate 131 according to a depth of the first groove 130_G, for example, a length of the first groove 130_G in the vertical direction (Z direction).

A connector 140 may be disposed on the PIC chip 130. For example, the connector 140 may be disposed in the first groove 130_G of the PIC chip 130. In one or more embodiments, a part of the connector 140 may protrude externally to the semiconductor package 1000 of the PIC chip 130.

In one or more embodiments, a transparent adhesive member 170 may be disposed between the connector 140 and the PIC chip 130. The connector 140 may be attached to the PIC chip 130 by using the transparent adhesive member 170. For example, the transparent adhesive member 170 may be disposed in the first groove 130_G of the PIC chip 130 and the second groove 141_G of the body 141 of the connector 140.

An optical fiber module 600 may be separably bonded to the connector 140. FIG. 3 illustrates that the connector 140 and the optical fiber module 600 are separated from each other, and FIG. 4 illustrates a case where the connector 140 and the optical fiber module 600 are bonded to each other.

The connector 140 may include a body 141, a connector waveguide 142, and a condensing portion 143.

The body 141 may include a first side surface 141_S1 and a second side surface 141_S2. The first side surface 141_S1 of the body 141 may face the second side surface 141_S2 of the body 141. At least a part of the second side surface 141_S2 of the body 141 may be disposed inside the first groove 130_G of the PIC chip 130. For example, a part of the second side surface 141_S2 of the body 141 may face one end of the waveguide 133 of the PIC chip 130.

In one or more embodiments, the body 141 may further include a second groove 141_G. The second groove 141_G may be recessed to the inside of the body 141 from the side surface and the lower surface of the body 141. The second groove 141_G may be disposed at the second side surface 141_S2 of the body 141.

For example, a portion that defines the side surface 141_G_S2 of the second groove 141_G of the second side surface 141_S2 of the body 141 may face the side surface 130_G_S of the first groove 130_G of the PIC chip 130. For example, the second groove 141_G of the body 141 may be disposed above the PIC chip 130, and the first groove 130_G of the PIC chip 130 may be disposed below the connector 140.

The body 141 may be configured to be separably bonded to the optical fiber module 600. As shown in FIG. 4, the optical fiber module 600 may be bonded to the first side surface 141_S1 of the body 141.

In one or more embodiments, the body 141 may include a coupling groove 141_H that extends inwards from the first side surface 141_S1 of the body 141, and an inner groove 141_SN formed in an inner wall of the coupling groove 141_H. A frame 610 of the optical fiber module 600 may include a protrusion 610_P configured to be inserted into the coupling groove 141_H, and a coupling hook 610_SN formed at an outer wall of the protrusion 610_P. When the protrusion 610_P of the frame 610 is inserted into the coupling groove 141_H of the body 141, the coupling hook 610_SN and the inner groove 141_SN may be configured in such a way that the coupling hook 610_SN may be inserted into the inner groove 141_SN.

For example, the optical fiber module 600 and the body 141 may be separably bonded to each other by using a snap-fit method. For example, the coupling hook 610_SN may be inserted into the inner groove 141_SN or the coupling hook 610_SN may be separated from the inner groove 141_SN by using an elastic force of the coupling hook 610_SN.

In one or more embodiments, the optical fiber module 600 may further include a manipulation button configured to manipulate the movement of the coupling hook 610_SN when a user presses the manipulation button. The user may detach the coupling hook 610_SN from the inner groove 141_SN using the manipulation button to separate the optical fiber module 600 and the connector 140 from each other.

However, embodiments are not limited thereto. and a method by which the optical fiber module 600 and the connector 140 are separably bonded to each other, is not limited to the above description, because the optical fiber module 600 may be separably bonded to the connector 140 in various known ways.

A connector waveguide 142 may pass through the inside of the body 141. The connector waveguide 142 may extend from the first side surface 141_S1 to the second side surface 141_S2 of the body 141. A first end disposed at the first side surface 141_S1 of the body 141 of both ends of the connector waveguide 142 may face an optical fiber 620 of the optical fiber module 600, and a second end disposed at the second side surface 141_S2 of the body 141 of both ends of the connector waveguide 142 may face the waveguide 133.

In one or more embodiments, vertical levels of both ends of the connector waveguide 142 may be different from each other. For example, the vertical level of a first end of the connector waveguide 142 may be higher than the vertical level of a second end of the connector waveguide 142 in the vertical direction (Z direction).

The connector waveguide 142 may be a path on which the optical signals OS move. In one or more embodiments, the refractive index of the connector waveguide 142 may be greater than the refractive index of the body 141. For example, the optical signals OS inside the connector waveguide 142 may be totally reflected between the connector waveguide 142 and the body 141 and may move along the connector waveguide 142. In one or more embodiments, the configuration material of the body 141 may be, for example, glass, and the connector waveguide 142 may be formed by condensing laser onto a part of glass or by performing chemical bonding on a part of glass.

Hereinafter, the condensing portion 143 will be described with reference to FIG. 5.

The condensing portion 143 may be disposed at one side of the body 141. The condensing portion 143 may be disposed at the second side surface 141_S2 of the body 141. The condensing portion 143 may be disposed at the side surface 141_G_S2 of the second groove 141_G of the second side surface 141_S2 of the body 141. For example, the condensing portion 143 may be adjacent to one end disposed at the second side surface 141_S2 of the body 141 of both ends of the connector waveguide 142 and may be disposed between the connector waveguide 142 and the waveguide 133.

The condensing portion 143 may be configured in such a way that the optical signals OS output from the connector waveguide 142 toward the PIC chip 130 may be condensed onto the waveguide 133 of the PIC chip 130. In addition, the condensing portion 143 may be configured in such a way that the optical signals OS output from the waveguide 133 of the PIC chip 130 may be condensed onto the connector waveguide 142. For example, the optical signals OS incident on the condensing portion 143 from one of the connector waveguide 142 and the waveguide 133 may pass through the condensing portion 143 and refracted and thus may be condensed onto the other of the connector waveguide 142 and the waveguide 133. In one or more embodiments, the refractive index of the condensing portion 143 may be different from the refractive index of the connector waveguide 142.

In one or more embodiments, the condensing portion 143 may include at least one lens. A focal point 143_F of the condensing portion 143 may be disposed in the waveguide 133 or the connector waveguide 142. For example, a focal length of the condensing portion 143 may be greater than or equal to a distance at which the side surface of the second groove 141_G of the body 141 and the side surface 130_G_S of the first groove 130_G of the PIC chip 130 are spaced apart from each other. The focal length of the condensing portion 143 may be greater than or equal to a distance at which a second end of the connector waveguide 142 and one end of the waveguide 133 of the PIC chip 130 are spaced apart from each other.

In one or more embodiments, the condensing portion 143 may be a convex lens. The condensing portion 143 may have a shape in which both sides of the condensing portion 143 are outwards convex. However, embodiments are not limited thereto, and the condensing portion 143 may have a shape in which a plurality of lenses are compressed, and may have a plurality of focal points.

In one or more embodiments, the thickness of the condensing portion 143, for example, a length of the condensing portion 143 in the vertical direction (Z direction), may be greater than a thickness of the waveguide 133. The thickness of the condensing portion 143 may be less than a depth of the second groove 141_G.

In one or more embodiments, the refractive index of the condensing portion 143 may be different from the refractive index of the connector waveguide 142. For example, the refractive index of the condensing portion 143 may be greater than the refractive index of the connector waveguide 142. For example, the condensing portion 143 may include elastomer or epoxy. In one or more embodiments, the condensing portion 143 may be formed by performing a nano imprinting process or an inkjet process on the body 141 in which the connector waveguide 142 is formed.

While the connector 140 is mounted on the PIC chip 130, the connector waveguide 142 of the connector 140 and the waveguide 133 of the PIC chip 130 may need to be aligned to face each other. While the connector waveguide 142 and the waveguide 133 are aligned, the optical signals OS may be condensed onto one point by using the condensing portion 143 of the connector 140 so that an alignment tolerance between the waveguide 133 and the connector waveguide 142 may be increased. As the tolerance is increased, the speed at which the connector 140 is mounted on the PIC chip 130 is enhanced so that the manufacturing speed of the chip structure 100 may be enhanced.

Referring back to FIG. 3, the dummy chip 160 may be disposed on the PIC chip 130. The dummy chip 160 may be spaced apart from the first groove 130_G of the PIC chip 130. In one or more embodiments, the dummy chip 160 may be spaced apart from the connector 140 in the horizontal direction.

In one or more embodiments, the dummy chip 160 may further include a dielectric layer 160_DL disposed at a lower surface of the dummy chip 160. The dielectric layer 160_DL of the dummy chip 160 may be bonded to the upper distribution structure 132 of the PIC chip 130. For example, the dielectric layer 160_DL of the dummy chip 160 and the upper distribution dielectric layer 160_DL of the PIC chip 130 may be integrally bonded to each other through diffusion bonding by heat. The dummy chip 160 and the PIC chip 130 may be bonded to each other through oxide-oxide bonding. However, a bonding method of the dummy chip 160 and the PIC chip 130 is not limited thereto, and the dummy chip 160 and the PIC chip 130 may be bonded to each other through an adhesive film or the like.

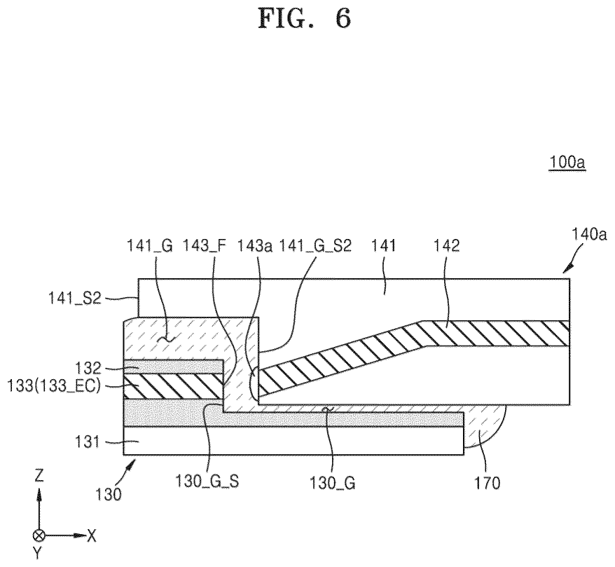

FIG. 6 is an enlarged view schematically illustrating a part of the chip structure 100 according to one or more embodiments.

Most components of a semiconductor package 1000a to be described below and materials for forming the components are substantially the same or similar to the previous description given with reference to FIG. 5. Thus, for convenience of description, differences between the chip structure 100a of FIG. 6 and the chip structure 100 of FIG. 5 described above will be described.

Referring to FIGS. 6 and 3, the chip structure 100a may include a redistribution structure 110, an EIC chip 120, a first molding layer 150, a PIC chip 130, a connector 140a, and a dummy chip 160.

The connector 140a may include a body 141, a connector waveguide 142, and a condensing portion 143a. The connector 140a may be attached on the PIC chip 130. For example, the connector 140a may be mounted on the PIC chip 130 by using the transparent adhesive member 170.

The PIC chip 130 may include a first groove 130_G recessed inwards from an upper surface and a side surface of the PIC chip 130, and the body 141 of the connector 140a may include a second groove 141_G recessed inwards from a second side surface 141_S2 and a lower surface of the body 141. For example, the connector 140a may be disposed on the PIC chip 130 so that a side surface 130_G_S of the first groove 130_G and a side surface 141_G_S2 of the second groove 141_G may face each other.

One end of the waveguide 133 of the PIC chip 130 may be exposed externally to the semiconductor package 1000 through the first groove 130_G, and one end of the connector waveguide 142 of the connector 140a may be exposed externally to the semiconductor package 1000 through the second groove 141_G. The waveguide 133 and the connector waveguide 142 may face each other. While the connector 140a is mounted on the PIC chip 130 through the second groove 141_G having a corresponding shape to the shape of the first groove 130_G, alignment between the waveguide 133 and the connector waveguide 142 may be facilitated.

The condensing portion 143a may be disposed at the second groove 141_G of the body 141. For example, the condensing portion 143a may be disposed at the side surface 141_G_S2 of the second groove 141_G of the body 141. The condensing portion 143a may be configured in such a way that optical signals emitted from one to the other one of the waveguide 133 or the connector waveguide 142 may be condensed onto the other one. For example, a focal point of the condensing portion 143a may be disposed on the waveguide 133 or the connector waveguide 142. For example, a focal length of the condensing portion 143a may be greater than or equal to a separation distance between the edge coupler 133_EC of the waveguide 133 and one end of the connector waveguide 142.

The condensing portion 143a may have a hemispherical shape. For example, the cross-section of the condensing portion 143a may have a semi-circular shape or a semi-elliptical shape. A side surface which the body 141 contacts, of side surfaces of the condensing portion 143a may have a flat shape, and a side surface spaced apart from the body 141, of the side surfaces of the condensing portion 143a may have a convex shape.

In one or more embodiments, while the condensing portion 143a of the connector 140a is formed, the condensing portion 143a separately produced may be attached into the second groove 140_G of the body 141. A separately produced side surface of the condensing portion 143a may be formed as a plane, and the condensing portion 143a may be attached to the body 141 so that the side surface that is a plane may be in contact with the body 141.

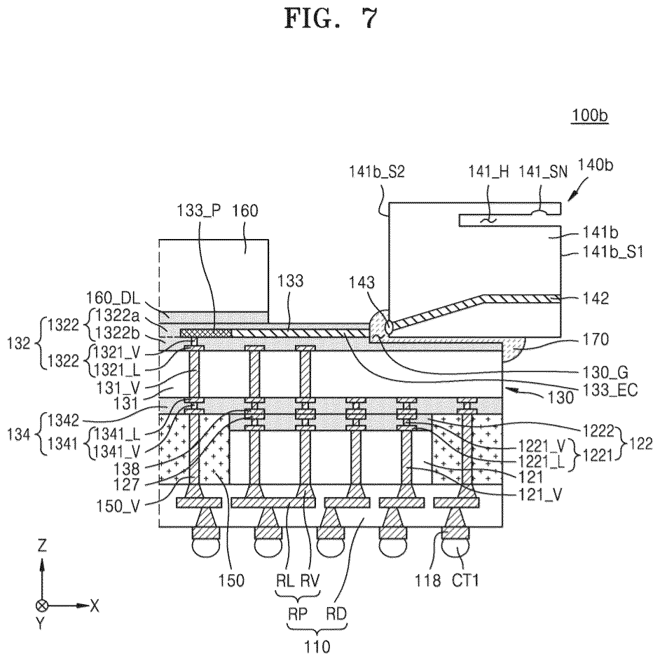

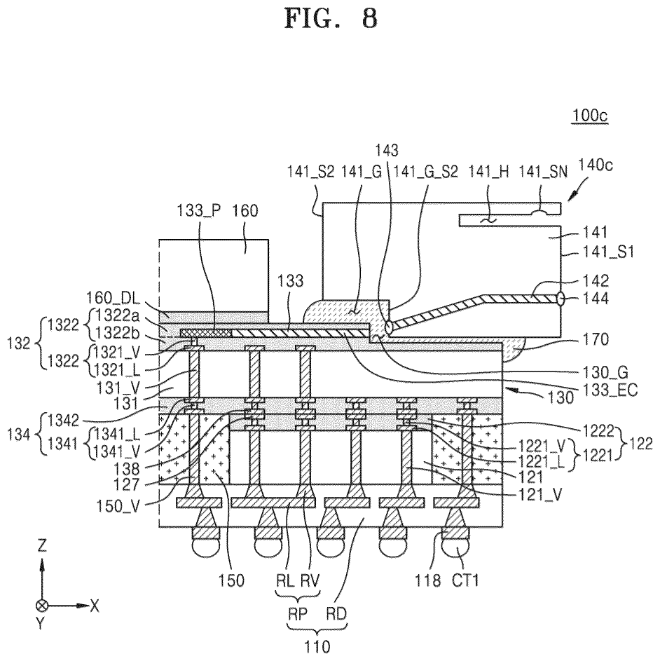

FIG. 7 is a cross-sectional view schematically illustrating a chip structure 100b according to one or more embodiments. FIG. 8 is a cross-sectional view schematically illustrating a chip structure 100c according to one or more embodiments.

Most components of the chip structures 100b and 100c to be described below and materials for forming the components are substantially the same or similar to the previous description given with reference to FIG. 3. Thus, for convenience of description, differences between the chip structures 100b and 100c of FIGS. 7 and 8 and the chip structure 100 of FIG. 3 described above will be described.

Referring to FIG. 7, the chip structure 100b may include a redistribution structure 110, an EIC chip 120, a first molding layer 150, a PIC chip 130, a connector 140b, and a dummy chip 160. The connector 140b may include a body 141b, a connector waveguide 142, and a condensing portion 143.

The connector 140b may be disposed on the PIC chip 130. For example, the connector 140b may be disposed in a first groove 130_G of the PIC chip 130. For example, a lower surface of the body 141b of the connector 140b may be mounted on a bottom surface of the first groove 130_G of the PIC chip 130.

The body 141b of the connector 140b may include a first side surface 141b_S1 and a second side surface 141b_S2 facing the first side surface 141b_S1. In one or more embodiments, the first side surface 141b_S1 of the body 141b may be disposed outside the photonic integrated circuit chip 130, and the second side surface 141b_S2 of the body 141b may be disposed on the PIC chip 130. For example, the second side surface 141b_S2 may be a plane. The second side surface 141b_S2 of the body 141b may be disposed on the first groove 130_G. The body 141b may not include a groove that extends inwards from the second side surface 141b_S2 of the body 141b of the connector 140b.

In one or more embodiments, while the connector 140b is formed, a process of manufacturing the body 141b may be more simplified so that the production speed of the connector 140b may be enhanced and the production yield of the connector 140b may be enhanced. In one or more embodiments, while the condensing portion 143 of the connector 140b is formed on the body 141b, the second side surface 141b_S2 of the body 141b may be a plane so that manufacturing of the condensing portion 143 may be facilitated. Also, an area in which an upper surface of the PIC chip 130 is exposed externally to the semiconductor package 1000, may be relatively increased so that dissipation of heat generated in the PIC chip 130 may be facilitated.

Referring to FIG. 8, the chip structure 100c may include a redistribution structure 110, an EIC chip 120, a first molding layer 150, a PIC chip 130, a connector 140c, and a dummy chip 160. The connector 140c may include a body 141, a connector waveguide 142, a condensing portion 143, and an external condensing portion 144.

The connector 140c may be disposed on the PIC chip 130. The connector 140c may be spaced apart from the dummy chip 160 in a horizontal direction. A part of the connector 140c may be disposed in the first groove 130_G of the PIC chip 130.

The connector 140c may be separably bonded to an optical fiber module (see 600 of FIG. 4). For example, the body 141 of the connector 140c may include a first side surface 141_S1 and a second side surface 141_S2 facing the first side surface 141_S1. The optical fiber module (see 600 of FIG. 4) may be bonded to the first side surface 141_S1 of the body 141, and the second side surface 141_S2 of the body 141 may be disposed on the PIC chip 130.

The body 141 may include a second groove 141_G that is recessed inwards from the second side surface 141_S2 and a lower surface of the body 141. The side surface 141_G_S2 of the second groove 141_G of the body 141 may face the side surface of the first groove 130_G of the PIC chip 130. For example, the connector 140c may be attached to the PIC chip 130 so that the first groove 130_G and the second groove 141_G may be engaged with the connector 140c.

The connector waveguide 142 may extend from the first side surface 141_S1 to the second side surface 141_S2 of the body 141. An end exposed from the first side surface 141_S externally to the semiconductor package 1000, of both ends of the connector waveguide 142 may be referred to as a first end, and an end exposed from the second side surface 141_S2 externally to the semiconductor package 1000 may be referred to as a second end. For example, the first end of the connector waveguide 142 may face an optical fiber (see 620 of FIG. 4) of the optical fiber module (see 600 of FIG. 4), and the second end of the connector waveguide 142 may face the waveguide 133 of the PIC chip 130.

The condensing portion 143 may be in contact with one end of the connector waveguide 142, and the external condensing portion 144 may be in contact with the other end facing one end of the connector waveguide 142. For example, the condensing portion 143 may be in contact with the second end of the connector waveguide 142, and the external condensing portion 144 may be in contact with the first end of the connector waveguide 142. For example, the condensing portion 143 may be disposed on the second side surface 141_S2 of the body 141, and the external condensing portion 144 may be disposed on the first side surface 141_S1 of the body 141. The condensing portion 143 may be disposed at the side surface 141_G_S2 of the second groove 141_G of the body 141.

The external condensing portion 144 may be configured in such a way that optical signals emitted from the connector waveguide 142 to the optical fiber (see 620 of FIG. 4) may be condensed onto the optical fiber (see 620 of FIG. 4). The external condensing portion 144 may be configured in such a way that optical signals emitted by the optical fiber (see 620 of FIG. 4) toward the connector waveguide 142 may be condensed onto the connector waveguide 142.

For example, the optical signals OS incident on the external condensing portion 144 from one of the connector waveguide 142 and the optical fiber may pass through the external condensing portion 144 and refracted and thus may be condensed onto the other of the connector waveguide 142 and the optical fiber.

In one or more embodiments, a focal length of the external condensing portion 144 may be greater than or equal to a separation distance between the optical fiber (see 620 of FIG. 4) and the body 141. In one or more embodiments, the refractive index of the external condensing portion 144 may be different from the refractive index of the connector waveguide 142. In one or more embodiments, the thickness of the external condensing portion 143, for example, a length of the external condensing portion 144 in the vertical direction (Z direction), may be greater than a thickness of the connector waveguide 142. In FIG. 8, the outer condensing portion 144 appears in a shape in which both sides of the outer condensing portion 144 are convex outwards, but the shape of the outer condensing portion 144 is not limited thereto.

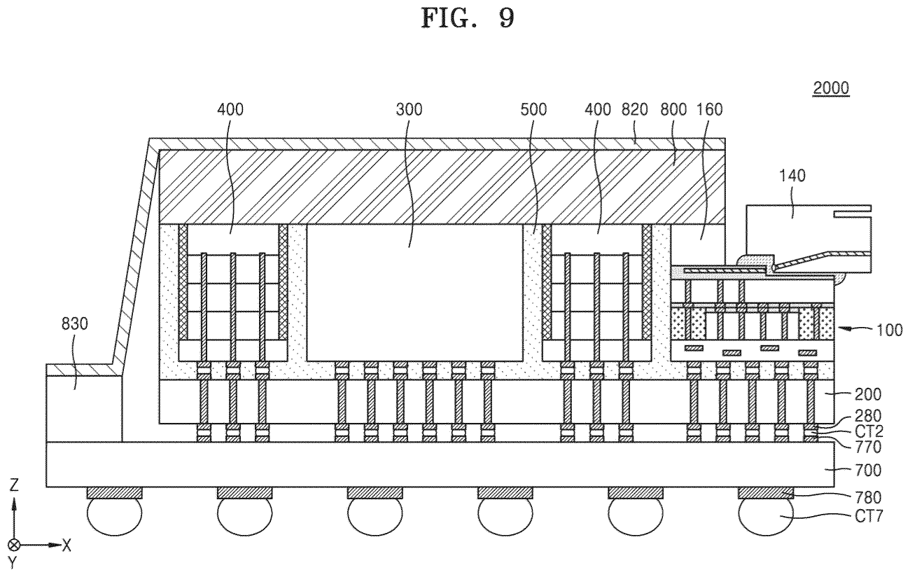

FIG. 9 is a plan view schematically illustrating a semiconductor package 2000 according to one or more embodiments.

Most components of the semiconductor package 2000 to be described below and materials for forming the components are substantially the same or similar to the previous description given with reference to FIG. 2. Thus, for convenience of description, differences between the semiconductor package 2000 of FIG. 9 and the semiconductor package 1000 of FIG. 2 described above will be described.

The semiconductor package 2000 may include a main substrate 700, a package substrate 200, a semiconductor chip 300, a plurality of stack structures 400, a chip structure 100, a second molding layer 500, and a heat sink 800.

The main substrate 700 may include a core insulating layer including at least one material selected from phenol resin, epoxy resin, and polyimide. For example, the core insulating layer may include at least one material selected from the group consisting of polyimide, flame retardant 4 (FR-4), tetrafunctional epoxy, polyphenylene ether, epoxy/polyphenylene oxide, bismaleimide triazine (BT), Thermount, cyanate ester, and liquid crystal polymer.

In one or more embodiments, the main substrate 700 may include an upper pad 770 disposed on the upper surface of the core insulating layer and a lower pad 780 disposed on the lower surface of the core insulating layer. The upper pad 770 and the lower pad 780 may be part of circuit distribution patterned after a Cu foil is coated on the upper surface and the lower surface of the core insulating layer. For example, the upper pad 770 and the lower pad 780 may be regions that are not covered by a solder resist layer of the circuit distribution and are exposed externally to the semiconductor package 2000.

In one or more embodiments, each of the upper pad 770 and the lower pad 780 may include Cu, Ni, stainless steel or beryllium copper. Internal distribution for electrically connecting the upper pad 770 to the lower pad 780 may be formed in the main substrate 700.

In one or more embodiments, external connection terminals CT7 may be attached to the lower pad 780. The external connection terminals CT7 may be configured to electrically and physically connect the main substrate 700 and an external device on which the main substrate 700 is mounted, to each other. The external connection terminals CT7 may be formed from, for example, solder ball or solder bumps.

The package substrate 200 may be attached to the main substrate 700. In one or more embodiments, the main substrate 700 and the package substrate 200 may be electrically connected to each other by the connection terminals CT2 disposed between the upper pad 770 of the main substrate 700 and the lower pad 280 of the package substrate 200.

The main substrate 700 may be a PCB, and the package substrate 200 may be an interposer. For example, the package substrate 200 may be used to electrically connect the semiconductor chip 300, the plurality of stack structures 400, and the chip structure 100 to the main substrate 700. For example, a pitch of the upper pad 270 of the package substrate 200 may be less than a pitch of the lower pad 280 of the package substrate 200.

The plurality of stack structures 400, the semiconductor chip 300, and the chip structure 100 may be attached to the package substrate 200. The second molding layer 500 may be disposed on the package substrate 200 and may surround the plurality of stack structures 400, the semiconductor chip 300, and the chip structure 100.

A vertical level of an upper surface of the second molding layer 500 may be equal to a vertical level of an upper surface of the plurality of stack structures 400, the vertical level of the upper surface of the semiconductor chip 300, and the vertical level of the upper surface of the dummy chip 160 of the chip structure 100 in the vertical direction (Z direction). The upper surface of the second molding layer 500, the upper surface of the plurality of stack structures 400, the upper surface of the semiconductor chip 300, and the upper surface of the dummy chip 160 of the chip structure 100 may be coplanar with each other.

The heat sink 800 may be disposed on the second molding layer 500. For example, the heat sink 800 may be disposed on the second molding layer 500, the plurality of stack structures 400, the semiconductor chip 300, and the dummy chip 160 of the chip structure 100. For example, the heat sink 800 may cover an upper surface of the second molding layer 500, upper surfaces of the plurality of stack structures 400, an upper surface of the semiconductor chip 300, and an upper surface of the dummy chip 160 of the chip structure 100. However, the heat sink 800 may be spaced apart from the connector 140 of the chip structure 100 in the horizontal direction.

The heat sink 800 may include a thermally conductive material having high thermal conductivity. The heat sink 800 may help dissipate heat generated from the plurality of laminated structures 400, the semiconductor chip 300, and the chip structure 100 externally to the semiconductor package 2000. For example, the heat sink 800 may include a metal such as Cu or Al, graphene, graphite, and/or a carbon-containing material such as carbon nanotubes. However, the material of the heat sink 800 is not limited to the above-described materials. In one or more embodiments, the heat sink 800 may include a single metal layer or a plurality of stacked metal layers.

In one or more embodiments, the semiconductor package 2000 may further include a case 820 and a supporter 830. The case 820 may be attached to the heat sink 800. The case 820 may cover an upper surface of the heat sink 800 completely to protect the heat sink 800, the second molding layer 500, and the package substrate 200 from the outside. In one or more embodiments, one side surface of the case 820 may be coplanar with one side surface of the heat sink 800, and the case 820 may not overlap the connector 140 of the chip structure 100 in the vertical direction (Z direction).

In one or more embodiments, a first region of the case 820 may be disposed on the heat sink 800, and a second region of the case 820 may be disposed on the main substrate 700. A bent portion of the case 820 may be disposed between the first region of the case 820 and the second region of the case 820 to connect the first region of the case 820 and the second region of the case 820 to each other. For example, the bent portion of the case 820 may be inclined from the upper surface of the main substrate 700 in the vertical direction (Z direction). For example, the inclination of the bent portion of the case 820 may be proportional to a difference between the vertical level of the first region of the case 820 and the vertical level of the second region of the case 820.

In one or more embodiments, the supporter 830 may be disposed on the main substrate 700. For example, the supporter 830 may be disposed between the case 820 and the main substrate 700. For example, the supporter 830 may be disposed under the second region of the case 820. The supporter 830 may reduce a difference between the vertical levels of the first region and the second region of the case 820. The inclination of the bent portion of the case 820 may be reduced through the supporter 830 so that formation feasibility and durability of the case 820 may be enhanced.

While embodiments have been described with reference to the figures, it will be understood by those of ordinary skill in the art that various changes in form and details may be made therein without departing from the spirit and scope as defined by the following claims and their equivalents.

What is claimed is:

1. A chip structure comprising:
a redistribution structure;
an electronic integrated circuit (EIC) chip on the redistribution structure;
a photonic integrated circuit (PIC) chip on the EIC chip, the PIC chip comprising:
a first groove recessed inwards from an upper surface of the PIC chip and a side surface of the PIC chip; and
a waveguide having a first end exposed externally to the chip structure through the first groove; and
a connector on the PIC chip, the connector comprising:
a connector waveguide passing through an inside of a body, a refractive index of the connector being greater than a refractive index of the body; and
a condensing portion on a side of the body,
wherein the condensing portion is configured to condense optical signals incident on the condensing portion from the connector waveguide to the waveguide of the PIC chip.

2. The chip structure of claim 1, wherein the connector waveguide included in the connector extends from a first side surface of the body included in the connector to a second side surface of the body included in the connector, facing the first side surface, and
wherein at least a part of the second side surface of the body included in the connector faces a side surface forming the first groove included in the PIC chip.

3. The chip structure of claim 2, wherein the body included in the connector is configured to separably mount an optical fiber module, and
wherein the optical fiber module is separably bonded to the first side surface of the body included in the connector.

4. The chip structure of claim 2, wherein the condensing portion included in the connector is on the second side surface of the body included in the connector.

5. The chip structure of claim 4, wherein the condensing portion included in the connector is in contact with a first end of the connector waveguide included in the connector and is between the waveguide included in the PIC chip and the connector waveguide included in the connector.

6. The chip structure of claim 4, wherein the connector further comprises an external condensing portion, and
wherein the external condensing portion is on the first side surface of the body included in the PIC chip and is in contact with a second end of the connector waveguide opposite to the first end of the connector waveguide.

7. The chip structure of claim 2, wherein the body included in the connector further comprises a second groove recessed inwards from a lower surface of the body and the second side surface of the body, and
wherein the second groove of the body included in the connector is above the PIC chip, and the first groove included in the PIC chip is below the connector in a vertical direction.

8. The chip structure of claim 7, wherein a portion forming a side surface of the second groove of the second side surface of the body faces a side surface of the first groove included in the PIC chip, and the condensing portion included in the connector is on a side surface of the second groove of the connector.

9. The chip structure of claim 1, wherein a thickness of the condensing portion included in the connector in a vertical direction is greater than a thickness of the waveguide included in the PIC chip in the vertical direction.

10. The chip structure of claim 1, wherein the condensing portion comprises at least one lens, and
wherein a focal point of the condensing portion is on the waveguide included in the PIC chip or the connector waveguide included in the connector.

11. The chip structure of claim 1, further comprising:
a first molding layer on the redistribution structure and on the EIC chip; and
a mold through via passing through the first molding layer and connecting the redistribution structure and the PIC chip to each other,
wherein the PIC chip is on the first molding layer and the EIC chip, and
a side surface of the redistribution structure, a side surface of the first molding layer, and a side surface of the PIC chip are coplanar with each other.

12. The chip structure of claim 1, further comprising a dummy chip on the PIC chip, wherein the dummy chip is spaced apart from the first groove included in the PIC chip.

13. A semiconductor package comprising:
a package substrate;
a semiconductor chip on the package substrate;
a chip structure on the package substrate and spaced apart from the semiconductor chip; and
a second molding layer on the package substrate and on the semiconductor chip and the chip structure,
wherein the chip structure comprises:
a redistribution structure on the package substrate;
an electronic integrated circuit (EIC) chip on the redistribution structure;
a photonic integrated circuit (PIC) chip on the EIC chip, the PIC chip comprising:
a first groove recessed inwards from an upper surface of the PIC chip and a side surface of the PIC chip; and
a waveguide of which a first end is exposed externally to the semiconductor package through the first groove; and
a connector on the PIC chip, the connector comprising:
a connector waveguide passing through an inside of a body; and
a condensing portion contacting a first end of the connector waveguide,
wherein the condensing portion is configured to condense optical signals incident on the condensing portion from the connector waveguide onto the waveguide of the PIC chip.

14. The semiconductor package of claim 13, wherein an area of the EIC chip of the chip structure is less than an area of the redistribution structure of the chip structure,
wherein the chip structure further comprises a first molding layer on the redistribution structure and on the EIC chip, and
wherein a side surface of the redistribution structure, a side surface of the first molding layer, and a side surface of the PIC chip are coplanar with each other.

15. The semiconductor package of claim 14, wherein a boundary surface is between the first molding layer and the second molding layer.

16. The semiconductor package of claim 14, wherein the chip structure further comprises a mold through via passing through the first molding layer and connecting the redistribution structure and the PIC chip to each other.

17. The semiconductor package of claim 13, wherein the chip structure further comprises a dummy chip disposed on the PIC chip and spaced apart from the connector in a horizontal direction, and
wherein an upper surface of the dummy chip, an upper surface of the semiconductor chip, and an upper surface of the second molding layer of the chip structure are coplanar with each other.

18. The semiconductor package of claim 17, further comprising a heat sink on the dummy chip, the semiconductor chip, and the second molding layer of the chip structure.

19. A semiconductor package comprising:
a package substrate;
a semiconductor chip on the package substrate;
a plurality of stack structures on the package substrate and spaced apart from the semiconductor chip;
a chip structure on the package substrate and spaced apart from the semiconductor chip;
a second molding layer on the package substrate, the semiconductor chip, and the chip structure; and
a heat sink on the second molding layer, the semiconductor chip, and the plurality of stack structures, and
wherein the chip structure comprises:
a redistribution structure on the package substrate;
an electronic integrated circuit (EIC) chip on the redistribution structure;
a first molding layer on the redistribution structure and the EIC chip;
a photonic integrated circuit (PIC) chip on the EIC chip and the first molding layer, the PIC chip comprising:
a first groove recessed inwards from an upper surface of the PIC chip and a side surface of the PIC chip; and
a waveguide having a first end is exposed externally to the semiconductor package through the first groove;
a connector comprising:
a body on the PIC chip and configured to be separably bonded to an optical fiber module;
a connector waveguide passing through the inside of the body, a refractive index of the connector waveguide being greater than a refractive index of the body; and
a condensing portion at one side of the body and configured to condense optical signals emitted from the connector waveguide onto the waveguide of the PIC chip; and
a dummy chip on the PIC chip, spaced apart from the connector, and below the heat sink in a vertical direction.

20. The semiconductor package of claim 19, wherein the condensing portion of the connector is in contact with a first end of the connector waveguide included in the connector and is between the waveguide of the PIC chip and the connector waveguide of the connector, and
wherein a focal length of the condensing portion of the connector is greater than or equal to a separation distance between the one end of the connector waveguide and the waveguide.
